(19) United States
(12) Patent Application Publication
(10) Pub. No.: US 2007/0040613 A1
(43) Pub. Date: Feb. 22, 2007

(54) Isolated stable bias circuit

(76) Inventors: Yut Hoong Chow, Penang (MY); Chin Kong Yong, Penang (MY); Boon Eu Seow, Penang (MY)

Correspondence Address: AVAGO TECHNOLOGIES, LTD., P.O. BOX 1920, DENVER, CO, 80201-1920, US

(21) Appl. No.: 11/208,978

(22) Filed: Aug. 19, 2005

(51) Int. Cl. H03F 3/04

(52) U.S. Cl. 330/296

(57) ABSTRACT

A biasing circuit is described for a radio frequency (RF) amplifier that provides a stable signal source. The described bias circuit has two or more transistors coupled in at least one feedback loop, with a buffering transistor providing the output biasing signal and buffering the feedback loops from the output of the of the biasing circuit. This arrangement provides thermal compensation, reduces fluctuations in the feedback loops that stabilize the biasing circuit, and allows for higher biasing current demand.

### TECHNICAL FIELD

The present invention is directed generally to processing radio frequency (RF) signals, and more particularly to providing a stable bias signal for RF devices.

### BACKGROUND OF THE INVENTION

In the normal processing and transmission of radio frequency (RF) signals, it is often useful to amplify the signals at one or more points in the processing or transmission path. RF signals may be amplified by using suitable semiconductor devices such as Field Effect Transistors (FETs), Bipolar Junction Transistors (BJTs) and the like. The operating point of such a device is typically determined, in part, by the biasing signal level, which is typically both voltage and current. Therefore, regulated direct current (DC) biasing voltages and currents are often used in order to bring the devices to desired operating conditions. One aspect of a device's operating point is the gain, which is the amplification ratio provided for the input signal.

Changes in the biasing voltage or current can generally change the operating point of a device that is amplifying an RF input signal, often triggering changes in the gain. In many applications, changes in gain may be undesirable. However, if the bias circuit, the circuit providing the biasing signal, is not stable, voltage and current variations may also occur, causing undesirable changes in the gain. Thus, because bias circuit instability may cause changes in the signal amplification ratio, it is often desirable to stabilize the bias circuit.

Various factors can negatively impact the stability of a bias circuit. One of these factors is the operating temperature. Operating temperature is the temperature of the devices comprising the bias circuit. Bias circuits often use transistors, and transistor operation may be affected by operating temperature. Therefore, without proper temperature compensation, a bias circuit is generally susceptible to changes in output voltage and current as a result of operating temperature variations.

Another factor is the effect of the RF input signal on the bias circuit itself. Both the bias circuit output voltage and the RF signal input voltage will typically be present at the same terminal of the amplifying transistor. This will usually be the gate, when using an FET, or the base, when using a BJT. The RF input signal will, therefore, have an opportunity to enter the bias circuit. Without some form of effective buffering to isolate the bias circuit from the RF input signal, the RF input signal might affect the operating characteristics of the bias circuit, resulting in a change in bias voltage or current. A strong enough RF signal may, therefore, change the gain of the amplifying transistor when the bias circuit lacks effective output buffering.

Yet another factor in bias circuit stability is the amount of bias current that is drawn by the amplifying transistor. One common solution for buffering the bias circuit output is to use a resistance in the range of several kiloOhms or larger. However, a resistance that is high enough to provide such buffering may also limit the amount of bias current that can be drawn by the amplifying transistor. Because devices that are capable of handling high power often also have a high bias current demand, the use of such resistance as a buffer will likely limit the power-handling capacity of the amplifying circuit. Alternatively, bias circuit output buffering may be provided by an inductance in the range of several nanoHenries or larger that passes DC signals, while significantly attenuating RF signals. Unfortunately, an inductor in this typical range is usually physically large, which may offset any potential advantages that a bias circuit might have for minimal or efficient use of chip space.

### BRIEF SUMMARY OF THE INVENTION

Representative embodiments of the present invention provide stable buffering and improved isolation for the bias circuit output, while allowing for both a compact circuit and a high current draw by the amplifying device. Stability is provided by at least one feedback loop, while isolation is provided by a buffering transistor that permits a higher current output than a resistance buffer and also avoids the space demands of an inductance buffer. The various embodiments of the present invention, thus, enable a high power RF amplifying device to be biased with improvements in both gain control and RF power output as compared to previous bias circuits.

The foregoing has outlined rather broadly the features and technical advantages of the present invention in order that the detailed description of the invention that follows may be better understood. Additional features and advantages of the invention will be described hereinafter which form the subject of the claims of the invention. It should be appreciated by those skilled in the art that the conception and specific embodiment disclosed may be readily utilized as a basis for modifying or designing other structures for carrying out the same purposes of the present invention. It should also be realized by those skilled in the art that such equivalent constructions do not depart from the spirit and scope of the invention as set forth in the appended claims. The novel features which are believed to be characteristic of the invention, both as to its organization and method of operation, together with further objects and advantages will be better understood from the following description when considered in connection with the accompanying figures. It is to be expressly understood, however, that each of the figures is provided for the purpose of illustration and description only and is not intended as a definition of the limits of the present invention.

### BRIEF DESCRIPTION OF THE DRAWINGS

For a more complete understanding of the present invention, reference is now made to the following descriptions taken in conjunction with the accompanying drawings, in which:

FIG. 1 is a circuit diagram illustrating an RF amplifier using a first standard bias circuit.

FIG. 2 is a circuit diagram illustrating an RF amplifier using another typically configured bias circuit.

FIG. 3 is a circuit diagram illustrating an RF amplifier using a bias circuit configured according to one embodiment of the present invention.

FIG. 4 is a circuit diagram illustrating an RF amplifier using a bias circuit configured according to another embodiment of the present invention.

FIG. 5 is a block diagram illustrating an embodiment of the present invention.

### DETAILED DESCRIPTION OF THE INVENTION

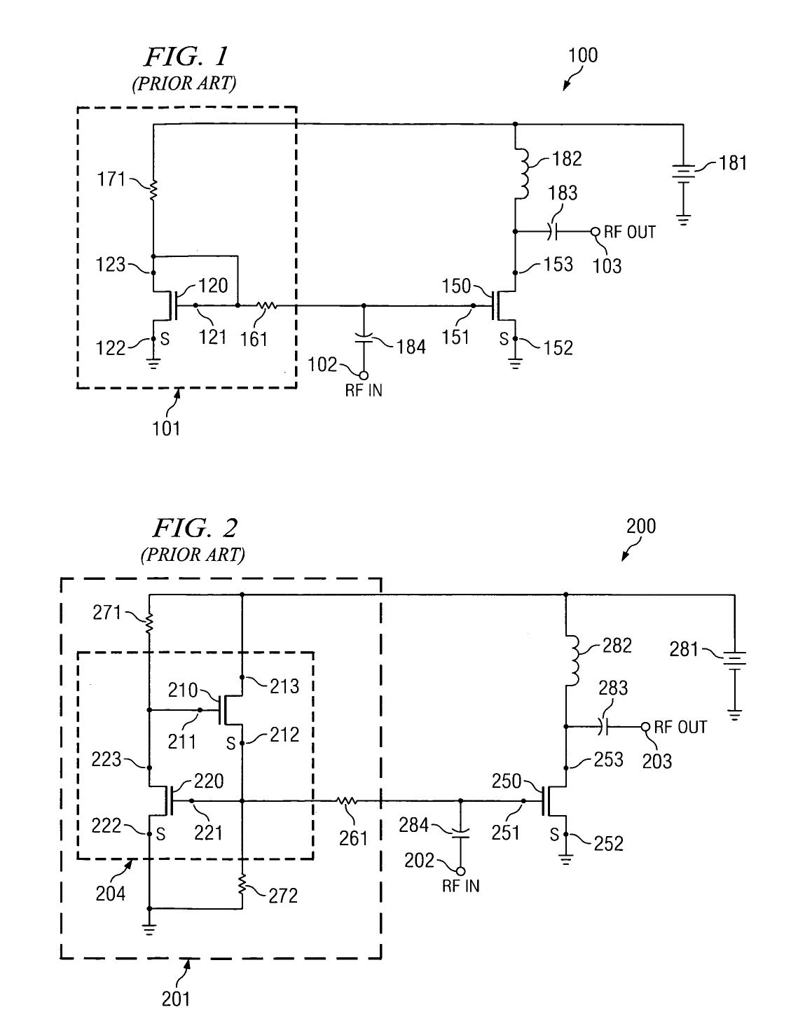

FIG. 1 is a circuit diagram illustrating RF amplifier 100 using first standard bias circuit 101. Standard bias circuit 101 is typically used for biasing an n-channel device amplifier. Examples of amplifying devices that may be used with such a circuit are pseudomorphic High Electron Mobility Transistors (pHEMTs), Metal-Oxide Semiconductor Field-Effect Transistors MOSFETs, BJTs, HBTs or the like.

In FIG. 1, FET 150 provides amplification of the RF signal. The RF signal enters at amplifier input 102 and exits at amplifier output 103. Capacitors 183 and 184 provide DC blocking. Amplifier 100 is powered by a suitable DC source, such as DC source 181, and inductor 182 helps direct the amplified RF signal to amplifier output 103. Amplifying FET 150 has source 152 grounded and drain 153 coupled to amplifier output 103 through DC blocking capacitor 183.

Bias circuit 101 comprises resistors 161 and 171 along with FET 120. It provides bias voltage and current to gate 151 of amplifying FET 150. FET 120 has gate 121 coupled to drain 123 in a single-transistor feedback loop. Source 122 of FET 120 is connected to ground. Resistor 161 provides isolation between gate 121 of FET 120 and gate 151 of amplifying FET 150. In alternative embodiments, resistor 161 may be replaced with an inductor or a combination of inductors and resistors. The advantages of bias circuit 101 are the minimal use of chip components and an economical use of chip real estate. However, bias circuit 101 has several disadvantages that can introduce instability, including a lack of thermal compensation.

One of the primary disadvantages of bias circuit 101 is that it generally cannot be used with a transistor that draws significant bias current. Since transistors that are capable of handling high power often have a high bias current demand, the use of bias circuit 101 will likely limit the power-handling capacity of the amplifying circuit. This is because resistor 161 is typically selected to be large enough to isolate gate 121 of FET 120 from the RF signal that is present at gate 151 of amplifying FET 150. A large value for resistor 161 may prevent gate 151 from receiving adequate bias current when the RF signal is at a high power, which can then lead to reduced output power. An alternative is to replace resistor 161 with an inductor. However, such an inductor is usually relatively large in order to provide adequate RF isolation. A large inductor removes the advantage that bias circuit 101 could make economical use of chip real estate. Hence, circuits similar to bias circuit 101 are typically only useful for small-signal amplifiers.

Another disadvantage is that the RF input signal to gate 151 of amplifying FET 150 also appears at gate 121 of FET 120, thereby affecting the instantaneous bias of FET 120. That is, after the RF input signal passes from amplifier input 102 through DC blocking capacitor 184, it appears at gate 151 of amplifying FET 150 and also passes through resistor 161 to appear at gate 121 of FET 120. The RF input signal thus enters the single-transistor feedback loop of bias circuit 101. This then perturbs the output of bias circuit 101, changing the bias—and therefore the gain—of amplifying FET 150. The closed-loop effect degrades the linearity of amplifier 100 because the gain fluctuates with input signal amplitude. In order to maintain stability and amplifier linearity, resistor 161 is typically selected to be a high value, which, as shown above, limits the power-handling capacity of amplifier 100.

FIG. 2 is a circuit diagram illustrating RF amplifier 200 using another typically configured biasing circuit, bias circuit 201. This second example of a typical biasing circuit, bias circuit 201, represents an improvement over first standard bias circuit 101, because it is more stable with respect to the bias voltage and current output. Specifically, it uses dual-transistor feedback loop 204, comprising FETs 210 and 220, that helps provide temperature compensation and reduces the effect of RF signal levels on the bias voltage and current levels.

In FIG. 2, FET 250 provides amplification of the RF signal. The RF signal enters at amplifier input 202 and exits at amplifier output 203. Capacitors 283 and 284 provide DC blocking. Amplifier 200 is powered by a suitable DC source, such as DC source 281, and inductor 282 helps direct the amplified RF signal to amplifier output 203. Amplifying FET 250 has source 252 grounded and drain 253 coupled to amplifier output 203 through DC blocking capacitor 283.

Bias circuit 201 comprises resistors 261, 271 and 272 along with FETs 210 and 220. Bias circuit 201 provides bias voltage and current to gate 251 of amplifying FET 250. FET 220 has gate 221 coupled to source 212 of FET 210, and drain 223 coupled to gate 211 of FET 210 in a dual-transistor feedback loop, which is a configuration well-known in the art. Source 222 of FET 220 is connected to ground, and drain 213 of FET 210 is coupled to DC voltage source 281. Resistor 261 provides isolation between feedback loop 204 and gate 251 of amplifying FET 250. In alternative embodiments of the type of circuit illustrated in FIG. 2, resistor 261 could be replaced with an inductor or a combination of inductors and resistors.

Bias circuit 201 is an improvement over bias circuit 101, because the dual-transistor feedback loop configuration both provides temperature compensation and exhibits more stability against the effects of RF signal levels on bias voltage and current levels. Nevertheless, bias circuit 201 still limits the bias current that can be drawn by amplifying FET 250, thus limiting the power-handling capacity of amplifier 200.

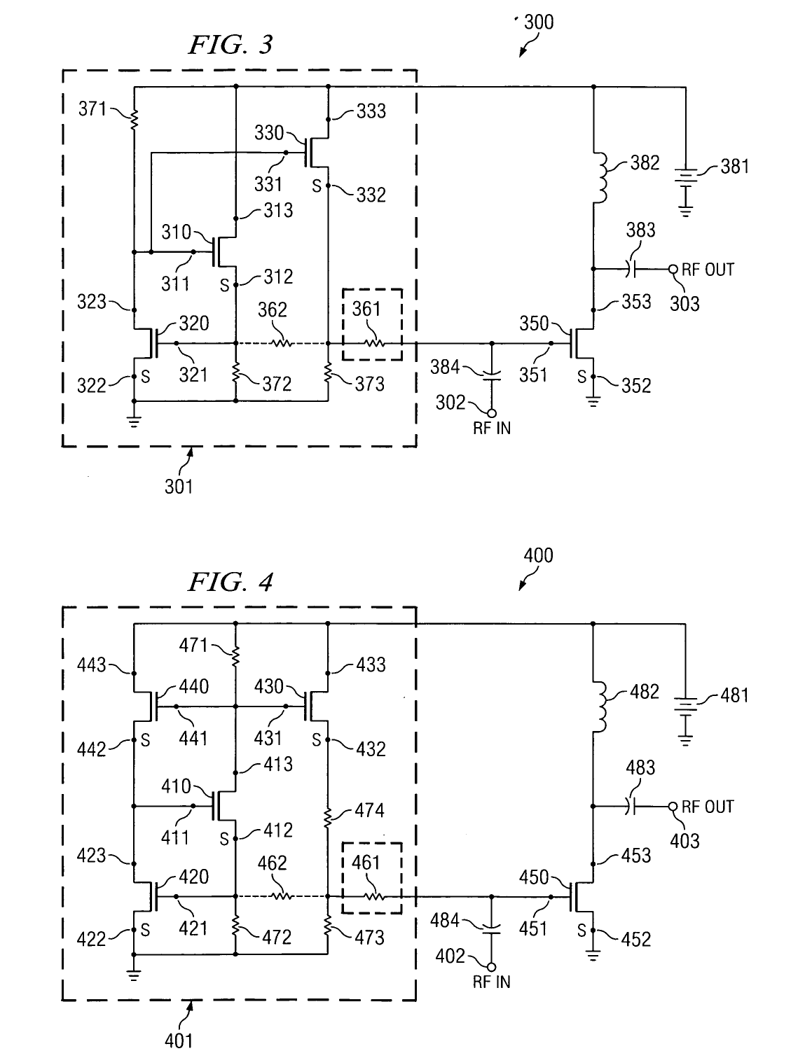

FIG. 3 is a circuit diagram illustrating RF amplifier 300 using bias circuit 301 configured according to one embodiment of the present invention. FET 350 provides amplification of the RF signal. The RF signal enters at amplifier input 302 and exits at amplifier output 303. Capacitors 383 and 384 provide DC blocking. Amplifier 300 is powered by a suitable DC source, such as DC source 381, and inductor 382 helps direct the amplified RF signal to amplifier output 303. Amplifying FET 350 has source 352 grounded and drain 353 coupled to amplifier output 303 through DC blocking capacitor 383. Bias circuit 301 provides bias voltage and current to gate 351 of amplifying FET 350, and comprises resistors 371, 372 and 373 along with FETs 310, 320 and 330.

In FIG. 3, FET 320 has gate 321 coupled to source 312 of FET 310, and drain 323 coupled to gate 311 of FET-310 in a dual-transistor feedback loop. Source 322 of FET 320 is connected to ground, and drain 313 of FET 310 is coupled to DC voltage source 381 along with drain 333 of buffering FET 330. Buffering FET 330 has its gate 331 coupled to gate 311 of FET 310, so that it is also driven by the feedback loop. However, source 332 of buffering FET 330 provides the bias circuit output current, rather than source 312 of FET 310. This configuration isolates the feedback loop comprising FETs 310 and 320 from the effects of the RF input signal, as well as allows a higher bias current draw by gate 351 of amplifying FET 350. Buffering FET 330 can be made to track the voltage of FET 310, which is operating in an isolated feedback loop with FET 320, by sizing FETs 310 and 330 along with resistors 373 and 372 to have equivalent physical and performance properties, respectively.

Bias circuit 301 solves the problems of previous bias circuits 101 and 201, namely the instabilities caused by temperature variation, high RF signal levels, and high bias current draw, as well as improves the power-handling capacity of amplifier 300. The dual-transistor feedback loop comprising FETs 310 and 320 provides temperature compensation and stability. By adding buffering FET 330 between the dual-transistor feedback loop comprising FETs 310 and 320 and gate 351 of amplifying FET 350, isolation is achieved between bias circuit 301 and the RF input signal at gate 351. This isolation is achieved in addition to enhanced bias current capacity. Since FET 330 is a current amplifier whose output impedance increases with frequency, the combination of FET 330 with resistor 373 acts as a space-efficient, synthetic inductor. Therefore, bias circuit 301 provides stability at higher current output levels than circuits 101 and 201, which then allows for gain consistency at higher power levels by amplifier 300 than by amplifiers 100 and 200.

In alternative embodiments, resistors 361 and 362 may be added to further improve isolation or fine tune gain consistency. Moreover, in alternative embodiments, resistors 361 and 362 may be a combination of resistance and inductance, but with values on the order of tens of Ohms and tenths of nanoHenrys, rather than the kiloOhms and nanoHenries required by bias circuits 101 and 201.

It should be noted that the various embodiments of the present invention are not limited to the specific configuration shown in FIG. 3. Various other bias circuit elements may be added and arranged suitably to provide a stable reference voltage or current, a voltage or current source that is driven by the reference, and a buffering element that isolates the reference voltage or current from changes in the voltage or current output without departing from the scope of the present teachings. In some embodiments, the current source driven by the reference may also act as the buffering element. Additionally, a voltage divider arrangement, similar to the one shown in the embodiment of FIG. 4 and described below, could also be used to more finely tailor the output bias voltage.

It should be further noted that the various embodiments of the present invention are not dependent on any particular IC technology and may also be used with pHEMTs, CMOSs, BJTs, HBTs, and other IC technologies. The basic topology of FIG. 3 could also easily be adapted to other bias configurations stacked on top of one another where higher bias voltages are required, such as those to bias MOSFETs. An example is shown using another embodiment of the present invention in FIG. 4.

FIG. 4 is a circuit diagram illustrating RF amplifier 400 using bias circuit 401 configured according to another embodiment of the present invention. In FIG. 4, FET 450 provides amplification of the RF signal. The RF signal enters at amplifier input 402 and exits at amplifier output 403. Capacitors 483 and 484 provide DC blocking. Amplifier 400 is powered by a suitable DC source, such as DC source 481, and inductor 482 helps direct the amplified RF signal to amplifier output 403. Amplifying FET 450 has source 452 grounded and drain 453 coupled to amplifier output 403 through DC blocking capacitor 483. Bias circuit 401 provides the bias signal to gate 451 of amplifying FET 450 and comprises resistors 471, 472, 473 and 474 along with FETs 410, 420, 430 and 440.

FET 420 has gate 421 coupled to source 412 of FET 410, and drain 423 coupled to gate 411 of FET 410 in a dual-transistor feedback loop. Source 422 of FET 420 is connected to ground. FET 440 has gate 441 coupled to drain 413 of FET 410 and DC voltage source 481 through resistor 471. Source 442 of FET 440 is coupled to gate 411 of FET 410 in a second dual-transistor feedback loop. Drain 443 of FET 440 is coupled to DC voltage source 481. Buffering FET 430 has gate 431 coupled to gate 441 of FET 440, so that buffering FET 430 is driven by the second feedback loop. Drain 433 of buffering FET 430 is coupled to DC voltage source 481, and source 432 of buffering FET 430 provides the bias circuit output current. In alternative embodiments, resistors 461 and 462 may be added to further improve isolation or fine tune gain consistency, and may be a combination of resistance and inductance.

The stacked configuration of bias circuit 401 in FIG. 4 provides twice the voltage for amplifying FET 450 as bias circuit 301 (FIG. 3) provides for amplifying FET 350 (FIG. 3). In addition, bias circuit 401 also includes a voltage divider comprising resistors 473 and 474 that may be adjusted to further tailor the output bias voltage. The advantages of this alternative embodiment include higher bias voltage as a result of the stacked transistor loops, with finer control over selecting the exact bias voltage as a result of the voltage divider.

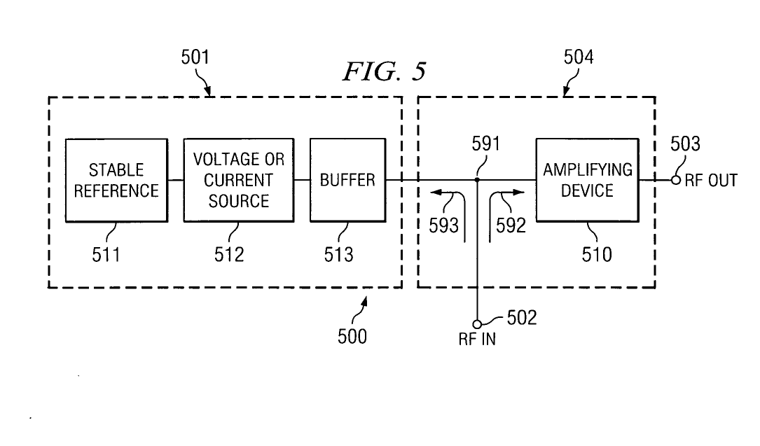

FIG. 5 is a block diagram illustrating one embodiment of the present invention. Amplifier 500 comprises bias circuit 501 and amplification circuit 504. Amplification circuit 504 comprises amplifying device 510 and common node 591. Amplification circuit 504 is coupled to amplifier input 502, amplifier output 503 and bias circuit 501. Bias circuit 501 comprises stable reference 511, signal source 512, which may be a current or voltage source, and buffer 513. Stable reference 511 drives and regulates signal source 512 to meet the biasing demands of amplifying device 510.

In operation, the RF signal enters at amplifier input 502 and then proceeds to common node 591 where it can take either intended path 592 into amplifying device 510 or unintended path 593 into bias circuit 501. Buffer 513 blocks the RF signal from entering stable reference 511, thus preventing the RF signal from affecting signal source 512. Buffer 513 also protects stable reference 511 from the current demands of amplifying device 510, thus stabilizing bias circuit 501, even in the presence of a high current demand by amplifying device 510. Various circuit elements can be used to implement the functional blocks of FIG. 5, including devices that simultaneously perform the function of more than one block.

Although the present invention and its advantages have been described in detail, it should be understood that various changes, substitutions and alterations can be made herein without departing from the spirit and scope of the invention as defined by the appended claims. Moreover, the scope of the present application is not intended to be limited to the particular embodiments of the process, machine, manufacture, composition of matter, means, methods and steps described in the specification. As one of ordinary skill in the art will readily appreciate from the disclosure of the present invention, processes, machines, manufacture, compositions of matter, means, methods, or steps, presently existing or later to be developed that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

What is claimed is:

1. A bias circuit comprising:
a first amplifier and a second amplifier coupled in a feedback loop; and
a third amplifier;
wherein a first terminal of the third amplifier is coupled to a first terminal of the first amplifier and a second terminal of the third amplifier is coupled to the output of the bias circuit.

2. The bias circuit of claim 1 wherein the first, second and third amplifiers comprise one or more transistors.

3. The bias circuit of claim 2 wherein the one or more transistors comprise one of:
Field Effect Transistors (FETs), wherein the first terminals of the first and third transistors are gate terminals; and
Bipolar Junction Transistors (BJTs), wherein the first terminals of the first and third transistors are base terminals.

4. The bias circuit of claim 1 wherein the second terminal of the third amplifier is coupled to the output of the bias circuit through a combination of resistance and inductance.

5. The bias circuit of claim 1 wherein the second terminal of the third amplifier is coupled to a second terminal of the first amplifier and a first terminal of the second amplifier.

6. The bias circuit of claim 5 wherein the second terminal of the third amplifier is coupled to the second terminal of the first amplifier and the first terminal of the second amplifier through a combination of resistance and inductance.

7. The bias circuit of claim 1 further comprising:
a voltage divider coupled to the bias circuit output.

8. A bias circuit comprising:
a first amplifier and a second amplifier coupled in a feedback loop;
a third amplifier; and
a fourth amplifier coupled in a feedback loop with the first amplifier;
wherein a first terminal of the third amplifier is coupled to a first terminal of the fourth amplifier and a second terminal of the third amplifier is coupled to the output of the bias circuit.

9. The bias circuit of claim 8 wherein the first, second, third and fourth amplifiers comprise one or more transistors.

10. The bias circuit of claim 9 wherein the one or more transistors comprise one of:
Field Effect Transistors (FETs), wherein the first terminals of the first and third transistors are gate terminals; and
Bipolar Junction Transistors (BJTs), wherein the first terminals of the first and third transistors are base terminals.

11. The bias circuit of claim 8 wherein the second terminal of the third amplifier is coupled to the output of the bias circuit through a combination of resistance and inductance.

12. The bias circuit of claim 8 wherein the second terminal of the third amplifier is coupled to a second terminal of the first amplifier and a first terminal of the second amplifier.

13. The bias circuit of claim 12 wherein the second terminal of the third amplifier is coupled to the second terminal of the first amplifier and the first terminal of the second amplifier through one or more of:
a resistance; and
an inductance.

14. The bias circuit of claim 8 further comprising:
a voltage divider coupled to the bias circuit output.

15. A method for biasing a radio frequency (RF) amplifier, said method comprising:
stabilizing a reference signal using a first feedback loop;
driving a first semiconductor device with the reference signal to provide a bias signal to the RF amplifier; and
isolating the first feedback loop from the RF amplifier through the first semiconductor device.

16. The method of claim 15 wherein the reference signal and the bias signal are each one of:
a predetermined voltage level; and
a predetermined current level.

17. The method of claim 15 wherein the first feedback loop comprises a second semiconductor device and third semiconductor device.

18. The method of claim 17 further comprising:
coupling a fourth semiconductor device to the third semiconductor device to form a second feedback loop.

19. The method of claim 15 further comprising:
dividing the voltage at the bias circuit output using passive devices.
